(19) United States
(12) Patent Application Publication
(10) Pub. No.: US 2017/0374744 A1
(43) Pub. Date: Dec. 28, 2017

(54) HEAT-SINKING COMPONENTS MOUNTED ON PRINTED BOARDS

(71) Applicant: Western Digital Technologies, Inc., San Jose, CA (US)

(72) Inventor: Michael T. Babin, SR., San Francisco, CA (US)

(21) Appl. No.: 15/696,614

(22) Filed: Sep. 6, 2017

Related U.S. Application Data
(63) Continuation of application No. 14/487,922, filed on Sep. 16, 2014.

(51) Int. Cl. H05K 3/22; B24B 37/30

(52) U.S. Cl. CPC H05K 3/22; B24B 37/30; H05K 2203/0165; H05K 2203/025; H05K 2203/0195

(57) ABSTRACT

In some examples, a method may include coupling a printed board assembly (PBA) to a fixture. In some examples, the PBA may include a printed board and a plurality of components that are electrically and mechanically coupled to the printed board, where each of the plurality of components defines a respective surface. The method may further include planarizing at least one of the respective surfaces of the plurality of components using an abrasive tool. The method may further include attaching a heat sink to the respective surfaces of the plurality of components. A system for planarizing surfaces of components attached to printed boards is also described.

### CROSS-REFERENCE TO RELATED APPLICATIONS

This application is a continuation application of co-pending U.S. patent application Ser. No. 14/487,922, filed on Sep. 16, 2014, which is incorporated herein by reference.

### TECHNICAL FIELD

This disclosure relates to heat sinks, and more particularly, to methods of heat sinking components mounted on printed boards.

### BACKGROUND

Solid state drives (SSDs) store information using solid state memory devices, such as flash memory devices. In order to achieve performance targets (e.g., data transfer rates), SSDs may utilize a plurality of flash memory devices electrically connected to a controller using a plurality of data channels. Read and write speeds to and from the flash memory devices may be affected by the number of data channels and the frequencies at which the controller and flash memory devices operate. Increasing the frequencies of the controller and flash memory devices may increase an amount of heat generated by the controller and the individual flash memory devices, other factors, such as process node and transistor type, being equal. Further, increasing the number of flash memory devices in a SSD may increase the total amount of heat generated, other factors, such as process node, transistor type, and operating frequency, being equal.

### SUMMARY

In some examples, the disclosure describes a method including coupling a printed board assembly (PBA) to a fixture. In some examples, the PBA may include a printed board (PB) and a plurality of components electrically and mechanically coupled to the PB, and each component of the plurality of components may define a respective surface. The method may further include planarizing at least one of the respective surfaces of the plurality of components using an abrasive tool. The method may further include attaching a heat sink to the respective surfaces of the plurality of components.

In some examples, the disclosure describes a system including a fixture configured to restrain a PBA and an abrasive tool. In accordance with these examples, the PBA may include a PB and a plurality of components electrically and mechanically coupled to the PB, and each component of the plurality of components may define a respective surface. At least one of the fixture or the abrasive tool may be configured to be moved relative to the other of the abrasive tool or the fixture to planarize at least one of the respective surfaces of the plurality of components such that the respective surfaces of the plurality of components lie in a substantially flat plane after planarization.

In some examples, the disclosure describes a system including means for restraining a PBA. The may include a PB and a plurality of components electrically and mechanically coupled to the PB, and each component of the plurality of components may define a respective surface. In accordance with these examples, the system also may include means for planarizing at least one of the respective surfaces of the plurality of components such that the respective surfaces of the plurality of components lie in a substantially flat plane after planarization.

The details of one or more examples are set forth in the accompanying drawings and the description below. Other features, objects, and advantages will be apparent from the description and drawings, and from the claims.

### BRIEF DESCRIPTION OF DRAWINGS

FIG. 1 is a conceptual and schematic diagram illustrating a side view of an example printed board assembly and an example system including a fixture and an abrasive tool.

FIG. 2 is a conceptual and schematic diagram illustrating a side view of an example printed board assembly and an example system including a fixture and an abrasive tool.

FIG. 3 is a conceptual and schematic diagram illustrating a side view of an example solid state drive including a printed board assembly, at least one heat sink, and a housing.

FIG. 4 is a flow diagram illustrating an example technique for planarizing a surface of at least one component of a printed board assembly.

### DETAILED DESCRIPTION

The disclosure describes techniques and systems for planarizing a surface of at least one component mounted to a printed board (PB) to facilitate coupling of a heat sink to the at least one component. Printed board assemblies (PBAs) include a PB and a plurality of components. In some examples, the components may include a plurality of active devices, such as controllers, flash memory devices, buffer memory devices, or the like. The techniques and systems may planarize the at least some respective surfaces of the components to facilitate coupling of a single heat sink to at least one of the components. In this way, the techniques and systems may facilitate assembly of a PBA and a heat sink, compared to requiring a separate heat sink for each component to be heat-sinked.

In some examples, a system for planarizing a plurality of components mounted to a PB may include a fixture and an abrasive tool. The fixture may be configured to hold or restrain the PB, and may include a material or shape that facilitates holding the PB substantially flat (planar) during the planarization technique. In some examples, a compliant film may be disposed between a rigid support of the fixture and the PB assembly. The compliant film may conform to non-planar features on a back side of the PB, such as solder bumps, while allowing the rigid fixture to hold the PB substantially planar during the planarization technique.

The abrasive tool may include any tool that defines a substantially planar surface and includes or utilizes an abrasive material to abrade material from a respective surface of one or more of the plurality of components to result in the respective surfaces lying in a substantially flat plane after the planarization technique. This may facilitate formation of a substantially uniform planar surface for attaching a heat sink to a plurality of components of the PBA. A substantially uniform planar surface for multiple components may facilitate more efficient assembly of the PBA and one or more heat sinks, while allowing sufficient thermal contact between the components and the heat sink. Similarly, the substantially uniform planar surface for multiple components may improve thermal contact between respective surfaces of the multiple components and the heat sink compared to instances where multiple components do not include the substantially uniform planar surface.

Planarizing respective surfaces for multiple components to lie in substantially the same plane may be facilitated by performing the planarization after the components are attached to the PB compared to individually planarizing surfaces prior to attaching the components to the PB. For example, the PB may not lie substantially in a plane, such that, even if the individual surfaces of the components are substantially planar, after connecting the components to the PB, the component surfaces may not lie in a substantially flat plane. Planarizing the respective surfaces after the components are attached to the PB also may result in the component surfaces lying in a substantially flat plane, even if the PB does not lie substantially in a plane.

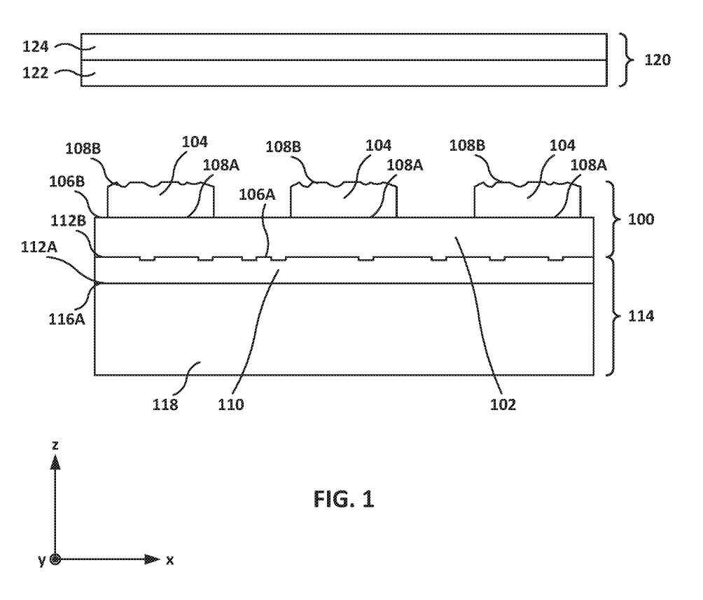

FIG. 1 is a conceptual and schematic diagram illustrating a side view of an example PBA 100 and a system including a fixture and an abrasive tool. PBA 100 may include a PB 102 and a plurality of components 104. In some examples, components 104 may be mechanically coupled to PB 102 and electrically coupled to electrically conductive traces or layers in or on PB 102. Components 104 may include electrical and electronic components, such as actives devices, passive devices, or both. Examples of active devices may include a controller, a host interface chip, a buffer memory (which may be part of the controller), flash memory devices, power delivery components, or the like. Examples of passive devices may include capacitors, resistors, inductors, or the like. In some examples, components 104 may be surface mounted, through-hole mounted, or a mixture of surface mounted and through-hole mounted. In some examples, components 104 may be attached to PB 102 using soldering, brazing, electrically conductive adhesive, or the like.

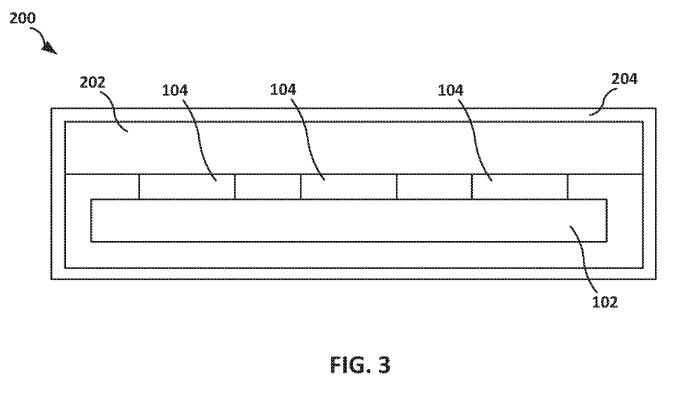

In some examples, PBA 100 may be part of a solid state drive (SSD) (e.g., SSD 200, FIG. 3). A SSD stores information using active devices such as flash memory. In some examples, the storage space of the SSD may be increased by increasing the number of flash memory devices. In some examples, increasing the number of flash memory devices also may increase the read/write speeds of the SSD, e.g., compared to an SSD with fewer flash memory devices and fewer data channels. In some examples, the performance (e.g., read/write speeds) also may be increased by increasing the operating frequency at which the active devices operate (including the controller, the flash memory devices, or both). Operation of components 104 may generate heat, and additional components 104, increased operating frequencies, or both, may increase a total heat generated by components 104 and PB 102 of PBA 100, when other factors are consistent.

PB 102 includes a plurality of surfaces, including a first PB surface 106A and a second PB surface 106B. First PB surface 106A may be substantially opposite to and substantially parallel to second PB surface 106B. First and second PB surfaces 106A and 106B may be the major (e.g., largest) surfaces of PB 102. In some examples, the plurality of components 104 may be attached to first PB surface 106A, to second PB surface 106B, or both. As illustrated in FIG. 1, in some examples, the plurality of components 104 may be attached only to second PB surface 106B.

In some examples, one or both of first PB surface 106A and second PB surface 106B may include surface features, non-uniformities, or non-planarity. In some examples, the surface features or non-uniformities may include solder bumps from soldering components 104 to PB 102, e.g., in through-hole mounting techniques. In some examples, the surface features or non-uniformities additionally or alternatively may include one or more components 104 attached to the respective PB surface 106A or 106B. For example, second PB surface 106B may include one or more passive or active components, one or more solder bumps, curvature such that second PB surface 106B is not substantially planar, or the like. As illustrated in FIG. 1, in some examples, first PB surface 106A may include surface features or non-uniformities such that first PB surface 106A is not substantially planar.

In some examples, one or more surfaces of at least one of components 104 may include surface non-uniformities. Each component 104 includes a respective first component surface 108A proximate to PB 102 and a respective second component surface 108B opposite of first component surface 108A and PB 102. In some examples, at least one of the respective second component surfaces 108B includes one or more surface non-uniformities, such as surface roughness or curvature that deviates from planarity. Surface non-uniformities of second component surfaces 108B may hinder thermal coupling between second component surfaces 108B and a heat sink thermally coupled to components 104.

In accordance with one or more examples of the disclosure, a system that includes a fixture 114 and an abrasive tool 120 may be used to substantially remove surface non-uniformities from one or more of second component surfaces 108B of components 104. Fixture 114 may be configured to restrain or hold PBA 100, e.g., during the planarization technique. In some examples, fixture 114 also may be configured to maintain PB 102 substantially planar when PBA 100 is restrained by fixture 114. In this way, fixture 114 may be configured to maintain components 104 substantially motionless relative to each other during the planarization technique.

In some examples, fixture 114 may include a substantially rigid support 118 and a compliant film 110. Substantially rigid support 118 may include a substantially rigid material, which may exhibit substantially no deformation (e.g., no deformation or nearly no deformation) under the forces exerted on substantially rigid support 118 during the planarization techniques described herein. Example materials from which substantially rigid support 118 may be formed include wood, metal, an alloy, a polymer or mixture of polymers, or the like.

In some examples, compliant film 110 may be disposed between PBA 100 and substantially rigid support 118. For example, as shown in FIG. 1, a first film surface 112A of compliant film 110 may be positioned adjacent to substantially rigid support 118 while a second film surface 112B of compliant film 110 may be opposite from first surface 112A and may be positioned to receive first PB surface 106A.

Compliant film 110 may include flexible and conforming material. For example, compliant film 110 may deform in response to contact with surface features, non-uniformities, or non-planarity of first PB surface 106A when PBA 100 is pressed against compliant film 110 during planarization of second component surfaces 108B. The material(s) from which compliant film 110 is formed may be selected to be sufficiently flexible to deform in response to contact with first PB surface 106A while being sufficiently resilient to exert a force against first PB surface 106A during the planarization technique. For example, compliant film 110 may be sufficiently inflexible that none of the surface features, non-uniformities, or non-planar portions of first PBA surface 106A contact substantially rigid support 118 during the planarization technique.

In some examples, compliant film 110 may possess adhesive properties, such that compliant film 110 at least partially restrains PBA 100 with respect to substantially rigid support 118. Compliant film 110 may be made of any suitable flexible material, including, wax, a foam tape, a polyurethane, or the like.

In other examples, instead of including compliant film 110, fixture 114 may include alternative mechanisms to support PBA 100 and, optionally, restrain PBA 100 relative to fixture 114. For example, fixture 114 may include a plurality of pillars or protrusions that extend from fixture surface 116A. The pillars or protrusions may be located at selected locations of fixture surface 116A such that the pillars or protrusions contact first PB surface 106A of PB and do not contact any components 104 that are attached to first PB surface 106A. Additionally, the pillars or protrusions may be sized such that any components 104 attached to first PB surface 106A do not contact fixture surface 116A when PBA 100 is pressed against the pillars or protrusions during the planarization technique.

As another example, fixture surface 116A may define a complementary shape to first PB surface 106A of PBA 100. In other words, fixture surface 116A may define a topology that is opposite to the surface topology of first PB surface 106A, such that the surface features of the first PB surface 106A substantially fit within the topology of fixture surface 116A and second PB surface 106B is maintained as a substantially flat plane during the planarization technique.

In some examples, fixture 114 may include one or more restraining devices, such as clamps, fasteners, clips, or the like. The one or more restraining devices may restrain PBA 100 relative to fixture 114 during the planarization technique. In some examples, the one or more restraining devices restrain movement of PBA 100 relative to fixture 114 in one or more of the x-, y-, and z-axes (where orthogonal x-y-z axes are shown in FIG. 1 for ease of description only).

The system also may include an abrasive tool 120. Abrasive tool 120 may define a substantially planar surface, such that abrasive tool 120 facilitated planarizing one or more of second component surfaces 108B. In some examples, abrasive tool 120 includes an abrasive film or layer, such as a lapping film 122, attached to a substantially rigid, substantially planar plate 124, as shown in FIG. 1.

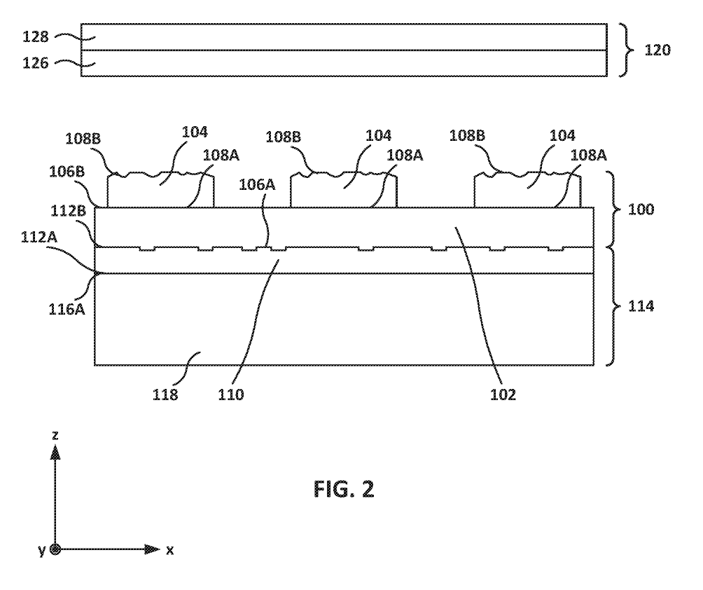

In other examples, as shown in FIG. 2, abrasive tool 120 may include an abrasive slurry 126 and a substantially planar plate 128. In some examples, abrasive slurry 126 may include abrasive particles or powder carried by a fluid. In some examples, lapping film 122 or abrasive slurry 126 may include materials such as aluminum oxide, emery, silicon carbide, diamond, or another abrasive material. In some examples, rigid plate 124 or substantially planar plate 128 may include a metal or charged composite plate.

The apparatus or device including abrasive tool 120 and fixture 114 may be used to reduce or substantially remove the surface non-uniformities of second component surfaces 108B of components 104 to result in second component surfaces 108B being disposed along a substantially flat plane. In some examples, one or both of abrasive tool 120 (e.g., substantially planar plate 124 or 128) or fixture 114 is configured to move relative to the other of abrasive tool 120 or fixture 114. In other examples, both abrasive tool 120 and fixture 114 are configured to move relative to one another.

As abrasive tool 120 moves relative to PBA 100, lapping film 122 or abrasive slurry 126 moves over the respective second component surfaces 108B of a plurality of components 104 and planarizes one or more of the respective second component surfaces 108B of the plurality of components 104. In some examples, abrasive tool 120 may be applied to individual components 104 to reduce or remove surface non-uniformities of that individual component. However, in some examples, abrasive tool 120 may be simultaneously or sequentially applied to the respective second component surfaces 108B of a plurality of electrical components 104, such that the plurality of electrical components 104 are polished or planarized as part of the same process. Not only may this be more efficient, this may facilitate formation of a substantially planar surface across multiple second component surfaces 108B.

By planarizing multiple second component surfaces 108B to lie in the same plane, a single heat sink may be thermally coupled to multiple (e.g., at least two) second component surfaces 108B while having desirable thermal contact between the heat sink and the respective second component surfaces 108B. This may allow simpler and/or faster assembly of PBA 100 with a heat sink compared to using a respective heat sink for each respective component of the plurality of components 104. Similarly, the substantially uniform planar surface for multiple components may improve thermal contact between respective surfaces of the multiple components and the heat sink compared to instances where multiple components do not include the substantially uniform planar surface.

Planarizing multiple second component surfaces 108B to lie in the same plane may be facilitated by performing the planarization after components 104 are attached to PB 102 compared to individually planarizing second components surfaces 108B prior to attaching components 104 to PB 102. For example, PB 102 may not lie substantially in a plane, such that, even if second component surfaces 108B are individually substantially planar, after connecting components 104 to PB 102, second component surfaces 108B may not lie in a substantially flat plane. Planarizing the respective second component surfaces 108B after components 104 are attached to PB 102 also may result in the respective second component surfaces 108B lying in a substantially flat plane, even if PB 102 does not lie substantially in a plane.

Although three components 104 are illustrated in FIG. 1, in other examples, PBA 100 may include more than three components 104. Generally PBA 100 may include a plurality of components 104. The planarization of multiple components 104 using fixture 114 and abrasive tool 120 may be performed on all of components 104 or a subset of components 104. Generally, fixture 114 and abrasive tool 120 may be used to planarize at least two second component surfaces 108B, and a single heat sink may be thermally coupled to at least two components 104. The heat sink may be thermally coupled to all of components 104 or a subset of components 104. In this way, a single heat sink may be used for multiple components 104, which may facilitate assembly, and the apparatus including fixture 114 and abrasive tool 120 may be used to form substantially planar surfaces of the multiple components 104 to facilitate thermal coupling of the heat sink to the components 104.

FIG. 3 is a conceptual and schematic diagram illustrating a side view of an example SSD 200 including PBA 100, at least one heat sink 202, and a housing 204. PBA 100 may be similar to or substantially the same as PBA 100 illustrated in FIGS. 1 and 2, and may include PB 102 and a plurality of components 104. Components 104 may include second component surfaces 108B, which have been planarized to lie in a substantially flat plane. In the example illustrated in FIG. 3, PBA 100 includes three components 104. In general, PBA 100 may include a plurality of components 104 (e.g., at least two components 104).

SSD 200 also includes at least one heat sink 202. In some examples, a single heat sink 202 may be thermally coupled to all of components 104. In other examples, heat sink 202 may be thermally coupled to a subset of components 104. In some examples, SSD 200 may include a plurality of heat sinks 202, each of which may be coupled to at least two components 104.

In some examples, heat sink 202 may be thermally coupled to the at least two components 104 using a thermal interface material such as thermal paste, a thermal adhesive, a thermal tape, or the like. In some examples, heat sink 202 may be mechanically coupled to at least PB 102 using clips, pins, compression springs, or other similar devices to retain heat sink 202 relative to PB 102 and components 104.

Heat sink 202 may include a thermally conductive material such as aluminum, copper, or the like. Heat sink 202 may be configured to transfer heat generated by components 104 to cool components 104. For example, heat sink 202 may have greater thermal mass than components 104, may have greater volume than components 104, may include geometric features such as fins that facilitate increased heat transfer, or may be thermally coupled to another component to which the heat may be transferred. In this way, heat sink 202 may facilitate cooling of components 104. Heat sink 202 may be passive cooled, actively cooled, or both. Passive cooling may include conduction of heat to another component, such as housing 204, passive convection, radiation, or the like. Active cooling may include forced air convection, liquid cooling using a pumped fluid, or the like.

SSD 200 also includes housing 204. Housing 204 may include a plurality of sides and defines an internal volume in which PBA 100 and heat sink 202 are disposed. In some examples, housing 204 may include a thermally conductive material, such as a metal, an alloy, a thermally conductive ceramic, a thermally conductive polymer or polymer doped to be thermally conductive, or the like. In some examples, heat sink 202 may be thermally coupled to housing 204 by a thermal interface material such as a thermal paste, a thermal adhesive, a thermal tape, or the like. In some examples, housing 204 may act as an extension of heat sink 202 to further dissipate heat from components 104.

Housing 204 may include one of several sizes, and may conform to one or various size standards for SSDs. In some examples, housing 204 may be sized as a 1.8 inch, 2.5 inch, or 3.5 inch form factor. However, in general, housing 204 may be any size.

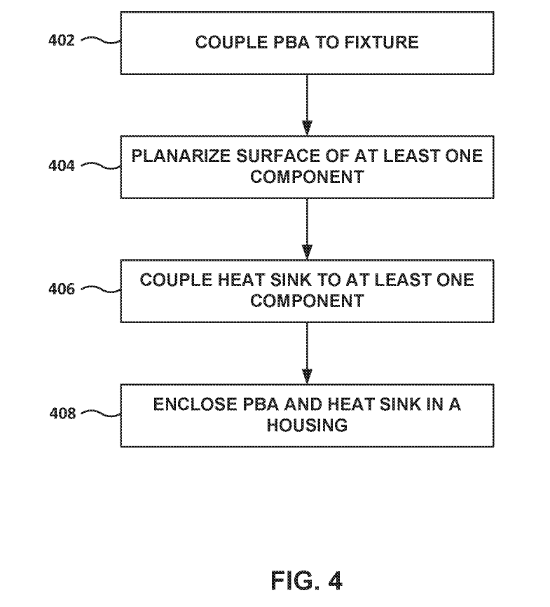

FIG. 4 is a flow diagram illustrating an example technique for planarizing components of a PBA. For purposes of description only, the technique of FIG. 4 will be described with reference to the system of FIG. 1. However, the technique FIG. 4 may be implemented with other systems, and the system of FIG. 1 may be formed using other techniques.

In some examples, the technique may include coupling PBA 100 to fixture 114 (402). As described in FIG. 1, in some examples, fixture 114 may include a substantially rigid support 118 and a compliant film 110. Coupling PBA 100 to fixture 114 (402) may include positioning compliant film 110 between PBA 100 and substantially rigid support 118. For example, as shown in FIG. 1, first film surface 112A of compliant film 110 may be positioned adjacent to substantially rigid support 118 while a second film surface 112B of compliant film 110 may be opposite from first surface 112A and may be positioned to receive first PB surface 106A. Thus, PBA 100 may be coupled to fixture 114 (402) by positioning first film surface 112A of compliant film 110 on fixture surface 116A, positioning a first PB surface 106A on second film surface 112B, and applying a force on PBA 100 and/or fixture 114 to couple PBA 100 to fixture 114. In some examples, compliant film 110 may include adhesive properties that help restrain PBA 100 relative to fixture 114. Compliant film 110 may deform in response to contact with surface features, non-uniformities, or non-planarity of first PB surface 106A when PBA 100 is pressed against compliant film 110.

In some examples, coupling PBA 100 to fixture 114 (402) may include alternative or additional mechanisms to support PBA 100 and, optionally, restrain PBA 100 relative to fixture 114. For example, fixture 114 may include a plurality of pillars or protrusions that extend from fixture surface 116A. The pillars or protrusions may be located at selected locations of fixture surface 116A such that the pillars or protrusions contact first PB surface 106A of PB 102 and do not contact any components 104 that are attached to first PB surface 106A.

In other examples, coupling PBA 100 to fixture 114 (402) may include positioning a first PB surface 106A of PBA 100 directly on fixture surface 116A. Fixture surface 116A may define a complementary shape to first PB surface 106A of PBA 100. In other words, fixture surface 116A may define a topology that is opposite to the surface topology of first PB surface 106A, such that the surface features of the first PB surface 106A substantially fit within the topology of fixture surface 116A and second PB surface 106B is maintained as a substantially flat plane during the planarization technique. Thus, PBA 100 may fit directly within fixture 114.

In some examples, fixture 114 may include one or more restraining devices, such as clamps, fasteners, clips, or the like. The one or more restraining devices may restrain PBA 100 relative to fixture 114 during the planarization technique. In some examples, the one or more restraining devices restrain movement of PBA 100 relative to fixture 114 in one or more of the x-, y-, and z-axes (where orthogonal x-y-z axes are shown in FIG. 1 for ease of description only). In these examples, coupling PBA 100 to fixture 114 (402) may include restraining PBA 100 relative to fixture 114.

After PBA 100 has been coupled to fixture 114 (402), at least one surface of at least one component 104 may be planarized using abrasive tool 120 (404). In some examples, abrasive tool 120 may include an abrasive film or layer, such as a lapping film 122, attached to a substantially rigid, substantially planar plate 124, as shown and described in FIG. 1. In other examples, as shown and described in FIG. 2, abrasive tool 120 may include an abrasive slurry 126 and a substantially planar plate 128.

In some examples, planarizing the respective surfaces of the plurality of components 104 (404) involves moving one or both of abrasive tool 120 or fixture 114 relative to the other of abrasive tool 120 or fixture 114. As abrasive tool 120 moves relative to PBA 100 or vice versa, lapping film 122 or abrasive slurry 126 moves over the respective second component surfaces 108B of plurality of components 104 and planarizes the respective second component surfaces 108B of the plurality of components 104. The planarization of multiple components 104 using fixture 114 and abrasive tool 120 may be performed on all of components 104 or a subset of components 104. In some examples, abrasive tool 120 may be applied to individual components 104 to reduce or remove surface non-uniformities of that individual component. However, in some examples, abrasive tool 120 may be simultaneously or sequentially applied to the respective second component surfaces 108B of a plurality of components 104, such that the plurality of components 104 are polished or planarized as part of the same process. Not only may this be more efficient, this may facilitate formation of a substantially planar surface across multiple second component surfaces 108B.

After planarization, in some examples, the technique of FIG. 4 includes thermally coupling at least one heat sink 202 a respective surface of at least two of the plurality of components 104 (406). In some examples, heat sink 202 may be thermally coupled to all of components 104, or to a subset of components 104. In some examples, a plurality of heat sinks may be thermally coupled to components 104; each heat sink 202 may couple to at least two planarized components 104. In some examples, heat sink 202 may be thermally coupled to components 104 by a machine in an automated process. In some examples, the at least one heat sink 202 may be thermally coupled to the respective components 104 (406) using a thermal interface material, such as a thermal paste, a thermal adhesive, a thermal tape, or the like.

In some examples, the technique of FIG. 4 optionally may include enclosing PBA 100 and heat sink 202 within a housing (408). In some examples, heat sink 202 may be thermally coupled to housing 204 (FIG. 3). In some examples, heat sink 202 may be thermally coupled to housing 204 using a thermal interface material, such as a thermal paste, a thermal adhesive, a thermal tape, or the like. PBA 100 may be mechanically coupled to housing 204 via screws, pins, clips, or the like. Heat sink 202 may be thermally coupled to housing 204. Housing 204 may protect PBA 100 from the external environment, and also may facilitate dissipation of heat generated by components 104.

Various examples have been described. These and other examples are within the scope of the following claims.

What is claimed is:

1. A method of manufacturing a solid state drive, comprising:
coupling electrically and mechanically a plurality of flash memory devices to a printed board;
coupling the printed board coupled with the plurality of flash memory devices to a fixture;
after the printed board is coupled to the fixture, planarizing a plurality surfaces of the plurality of flash memory devices using an abrasive tool, the plurality of surfaces facing away from the coupled printed board coupled to the fixture; and
attaching a heat sink to the plurality of surfaces of the plurality of flash devices to form a printed board assembly comprising the printed board, the plurality of flash memory devices, and the heat sink.

2. The method of claim 1, further comprising:
positioning the printed board assembly within an internal volume of a housing, the housing comprising a thermally conductive material; and
thermally coupling the printed board assembly and the thermally conductive material of the housing.

3. The method of claim 1, wherein the fixture includes a substantially rigid support and a compliant film, and wherein coupling the printed board to the fixture comprises:
positioning the compliant film between a first surface of the printed board and the substantially rigid support, wherein a second surface of the printed board comprises at least two of the plurality of flash memory devices, wherein the first surface of the printed board is opposite of the second surface, and wherein the compliant film is configured to conform to surface features on the first surface of the printed board.

4. The method of claim 3, wherein the compliant film comprises a polyurethane film.

5. The method of claim 1, wherein the fixture defines a surface configured to hold the printed board substantially planar while planarizing the at least one of the respective surfaces.

6. The method of claim 1, wherein planarizing at least one of the respective surfaces of the plurality of flash memory devices further comprises moving a substantially planar surface of the abrasive tool in a direction substantially parallel to the substantially planar surface relative to the surfaces of the plurality of flash memory devices.

7. The method of claim 1, wherein the surfaces of the plurality of flash memory devices are surfaces substantially parallel to a major surface of the printed board.

8. The method of claim 1, wherein the abrasive tool comprises a lapping film on a rigid plate.

9. The method of claim 1, wherein the abrasive tool comprises an abrasive slurry and a substantially planar plate.

10. The method of claim 3, wherein the compliant film comprises a flexible and conforming material.

11. The method of claim 3, wherein the compliant film comprises a foam tape.

12. The method of claim 3, wherein the compliant film is configured to conform to non-planar features of the printed board.

13. A method of manufacturing a solid state drive, comprising:
coupling a plurality of first surfaces of a plurality of flash memory devices to a printed board;
after the flash memory devices are coupled to the printed board, planarizing a plurality of second surfaces of the flash memory devices to form a substantially flat plane;
forming a single heat sink covering the planarized second surfaces of the flash memory devices; and
enclosing the flash memory devices, the printed board, and the single heat sink within a housing.

14. The method of claim 13, wherein a surface of the print board has non-uniformities.

15. The method of claim 13, wherein a surface of the print board coupled to the plurality of flash memory devices has non-uniformities.

16. The method of claim 15, wherein the non-uniformities of the surface of the printed board is selected from the group consisting of solder bumps, passive components, active components, and curvature.

17. A method of manufacturing a solid state drive, comprising:
coupling a plurality of first surfaces of a plurality of solid state memory devices to a printed board;
after the solid state memory devices are coupled to the printed board, planarizing a plurality of second surfaces of the solid state memory devices to form a substantially flat plane;
forming a single heat sink covering the planarized second surfaces of the solid state memory devices; and
enclosing the solid state memory devices, the printed board, and the single heat sink within a housing, the housing thermally coupled to the single heat sink.

18. The method of claim 17, wherein a surface of the print board has non-uniformities.

19. The method of claim 17, wherein a surface of the print board coupled to the plurality of solid state memory devices has non-uniformities.

20. The method of claim 15, wherein the non-uniformities of the surface of the printed board is selected from the group consisting of solder bumps, passive components, active components, and curvature.
